(19) United States
(12) Patent Application Publication
(10) Pub. No.: US 2009/0253386 A1
(43) Pub. Date: Oct. 8, 2009

(54) VOLTAGE-CONTROLLED OSCILLATOR (VCO)

(75) Inventors: Francois Gagnon, Lachine (CA); Jonathan Gagnon, Montreal (CA)

Correspondence Address: BERESKIN AND PARR LLP/S.E.N.C.R.L., s.r.l., 40 KING STREET WEST, BOX 401, TORONTO, ON, M5H 3Y2, CA

(73) Assignee: ECOLE DE TECHNOLOGIES SUPERIEURE, Montreal, QC (CA)

(21) Appl. No.: 12/307,406

(22) PCT Filed: Jul. 19, 2007
(86) PCT No.: PCT/CA2007/001292

§ 371 Date: Jan. 5, 2009

Related U.S. Application Data
(60) Provisional application No. 60/807,986, filed on Jul. 21, 2006.

(51) Int. Cl. H04B 1/38; H03B 5/12

(52) U.S. Cl. 455/90.1; 331/117 R

(57) ABSTRACT

The present invention relates to a Voltage-Controlled Oscillator (VCO) and to use of the VCO in a high-temperature sensor transceiver. The VCO has a voltage input and a frequency of oscillation dependent on the voltage input. The VCO includes a transistor providing a gain allowing for a sustained oscillation. The transistor also has a capacitance that varies as a function of the voltage input. The high-temperature sensor includes a high-temperature sensor operatively coupled to the VCO for wireless transmission of an output signal of the sensor.

### FIELD OF THE INVENTION

The present invention relates to a voltage-controlled oscillator, and more precisely to a voltage-controlled oscillator circuit.

### BACKGROUND OF THE INVENTION

Voltage-controlled oscillators (VCO's) typically use a variable capacitor (varactor) as part of the circuit. Having such a component within the VCO can make circuit design challenging: for example in high operating temperature environments or in cases when simpler or less costly circuit designs are desirable.

Sensor Networks are currently used in various industries for many purposes; among those are surveillance and condition monitoring. Surveillance is used extensively for national security to do area monitoring and target detection/classification. Examples of areas where condition monitoring is used are machine, animal, vehicle, medical conditions, and environmental changes monitoring. For example, smart buildings are designed using sensor networks acting on parameters such as ambient temperature. Wired sensor networks are limited since the use of wires or cables is impractical for several applications, such as surveillance or in dynamic environments. Moreover, the cost of communication cabling can be significant for some applications. Wireless sensor networks (WSN) overcome these limitations by the addition of radio transceivers that allow for wireless communication of measurements. However, wireless communication is more subject to environmental constraints, such as wave propagation and interference, than wired communication.

The elements arranged in wireless sensor networks consist of three parts: a sensor or actuator, a power source, and a radio transceiver. The wireless sensor networks currently in use are not rugged since they operate in environments where the temperature is below the maximum operating temperature of conventional electronics (<125° C.). Designing rugged sensor networks for operation in harsh environments is still a technical challenge. The lack of qualified electronic components for the design of a rugged radio transceiver has prevented the deployment of wireless sensor networks in harsh environments.

There is therefore a need for a voltage-controlled oscillator capable of overcoming some problems of current oscillators.

### SUMMARY OF THE INVENTION

The present invention provides a voltage-controlled oscillator that relies on variable capacitance properties of a transistor.

In a first aspect, the present invention relates to a Voltage-Controlled Oscillator (VCO) having a voltage input and a frequency of oscillation dependent on the voltage input. The VCO includes a transistor providing a gain allowing for a sustained oscillation and having a capacitance that varies as a function of the voltage input.

In another aspect, the present invention relates to a High Temperature Voltage-Controlled Oscillator (HTVCO) having a voltage input and a frequency of oscillation dependent on the voltage input. The HTVCO includes a transistor having a capacitance that varies as a function of the voltage input applied thereto.

In yet another aspect, the present invention relates to a high-temperature sensor transceiver including the HTVCO and a high-temperature sensor operatively coupled the HTVCO for wireless transmission of an output signal of said sensor.

### BRIEF DESCRIPTION OF THE DRAWINGS

FIG. 1 shows a rugged sensor transceiver utilisation context;

FIG. 2 shows a schematic of an exemplary 37 MHz VCO;

FIG. 3 shows a schematic of an exemplary HTVCO;

FIG. 4 shows measured prototype frequency versus input voltage (Vg) and temperature (° C.);

FIG. 5 shows measured oscillation power versus input voltage (Vg) and temperature (° C.); and

FIG. 6 shows a prototype of an HTVCO.

### DETAILED DESCRIPTION OF THE INVENTION

Rugged wireless sensor networks (RWSN) provide an answer to the needs for measurement and monitoring in harsh environments. It provides new possibilities by enabling measurements that were simply not possible before, such as inside an aircraft engine for example, or by providing increased reliability to sensor networks used for national security.

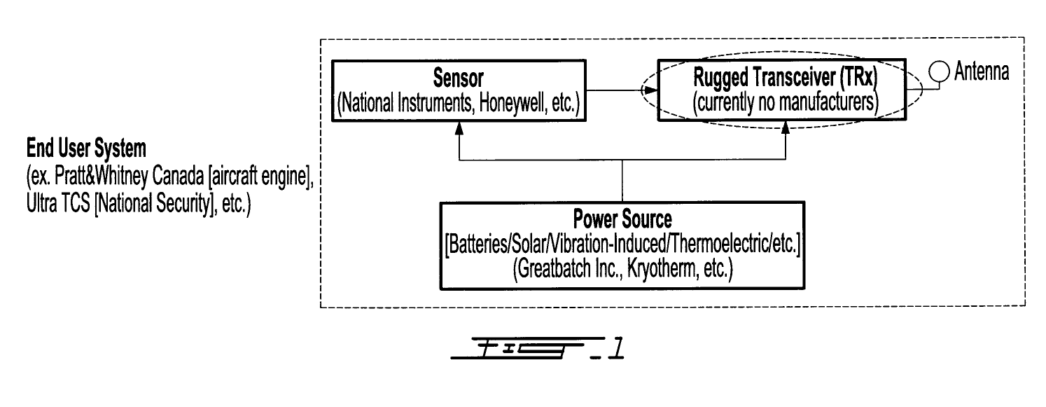

Since one of the bottlenecks of RWSN implementation is the communication module, an objective of the present invention is to be used in developing a rugged wireless transceiver for a sensor network. Such a transceiver must be resistant to high temperatures, intense vibrations, and electromagnetic interference (EMI). FIG. 1 shows the utilisation context of such a transceiver as part of an end-user system. The network elements of a rugged wireless sensing system are composed of a sensor, a power source, and a rugged transceiver.

Various scientific issues must be taken into consideration while developing a rugged transceiver. The first issue of concern is the mechanical design of the device to allow it to sustain high temperatures, high levels of vibrations and EMI. To do so, the impact of thermal cycling, heat exchange and stress on circuit operation must be minimized. The use of the silicon-on-insulator (SOI) technology reduces the concern of heat exchange inside the device since the active electronic components can function at higher temperatures. However, heat exchange remains an important design factor that needs to be considered in the selection of proper packaging solutions. Vibrations and high heat have a large impact on the strain that is put on joints between the board and its components. Adequate materials selection and verification of their behaviour and interactions at the projected operation temperature will be important to a successful design. For example, the coefficients of thermal expansion (CTE) of the different materials used must be similar in value to avoid the breakdown of joints. The actual operating temperature of the designed emitter is 270° C. and such a limit is yet to be improved to ensure reliability in harsh environments over long periods of time. The second issue, which is addressed by electrical or system design, comes from temperature variations. Depending on the operating temperature, the oscillating frequency of the voltage-controlled oscillator (VCO), which is used in both the emitting and transmitting modules, varies slightly. This is caused by the temperature dependence of the electronic components which changes in value lead to the change in oscillating frequency. It will be useful, even of great importance in the case of a transceiver network, to be able to track the frequency of an emitter as temperature changes. Another solution would be to stabilise the oscillating frequency and make it immune to temperature variations, for example by monitoring temperature and adjusting the voltage bias accordingly.

Transceivers for high-temperature applications, having networking capabilities or not, result from custom design and are not commercially available off-the-shelf. In some embodiments, the present invention combines harsh environment resistance with networking ability. It functions preferably at low data transmission rates. This will improve the reliability of the transmission, and is acceptable given the fact that sensors do not usually transmit large amounts of data.

Applications of wireless sensor networks are numerous. The application of wireless sensor networks to turbine engines is advantageous. As more and more sensors are added for engine monitoring by the aerospace industry, the need for electronics resisting harsh environments is growing. Such electronics is currently needed for improvement of the research and development phase of aircraft engines, and eventually might offer possibility for in-flight monitoring and measurements. This, in turn, will allow for faster maintenance and design modifications leading to performance improvements. The fact that several parts of an engine cannot be connected to the external environment by wire makes the aerospace industry a potential market for high-temperature rugged wireless telemetry. Moreover, as the number of sensors increases, the weight of wires and cables becomes more significant, providing an additional argument in favour of the wireless solution. The main player benefiting from technological advances in the field of aircraft engines is the airplane operator. The cost of operation of an airplane is one of his major concerns. Engine maintenance costs cover 30% of the total operation charges, as documented in “Large Engine Maintenance Technique to Support Flight Operation for Commercial Airlines”, authored by Tanaka, Y., Nagai, S., Ushida, M. & Usui, T., published by Mitsubishi Heavy Industries Ltd., Technical Review Vol. 40 No. 2, (April 2003). This translated, for Air Canada, into 2.63B$ for the maintenance of their 319 jets in 2004, as detailed in a publication titled Gestion ACE Aviation Inc., (November 2005), Rapport de gestion—Troisième trimestre 2005, available on Air Canada Web site at www.aircanada.com.

Rugged wireless sensor technologies thus constitute a promising solution for minimizing the time required for maintenance and increasing the time between overhauls (TBO), as proposed by Simon, D. L., Gang, S., Hunter, G. W., Guo, T.-H. & Semega, K. J. (2004), in “Sensor Needs for Control and Management of Intelligent Aircraft Engines” published in NASA Technical Bulletin #TM-2004-213202. Reducing those costs will result in significant economical gains for the end-user. Moreover, the premium charges for advanced engine health monitoring via RWSN are marginal with respect to the value of a turbine engine.

Another possible application of wireless sensor networks is in the field of national security. The increased interest for national security introduces a need for fast-deployment monitoring systems. National security usually refers to: military communications, police, paramedics, fire fighters, etc. . . . The use of wireless sensor network technology provides a solution that enables efficient and reliable military surveillance systems. Applications are numerous; such systems can be arranged around strategic perimeters, or distributed over targeted areas, to set up motion detection borders or any type of sensors. Forest fire fighters might use a wireless network of temperature sensors, in woods considered at-risk for fire, to monitor the heat evolution and then minimize reaction time. However, the national security sets the bar for reliability and resistance at heights beyond most of their civil counterparts. Using sensor network technologies for such applications requires robustness as well as imperviousness to a plurality of physical constraints.

One known weak component in today's technologies to develop and commercialize such rugged transceivers and wireless sensors is at the oscillator level. Transceivers and wireless sensors require use of an oscillator for radio-frequency generation. More precisely, transmitters and receivers need to have a VCO capable of stabilizing the oscillating frequency against temperature variations. The following paragraphs provide a description of a VCO in accordance with aspects of the present invention.

In accordance with the present invention, the variable capacitance properties of a transistor (e.g. Field Effect Transistor or Bipolar Junction Transistor) is used to advantage to provide oscillator circuits suitable for high operating temperature environments or in cases when simpler or less costly circuit designs are desirable. For doing so, the present invent provides a Voltage-Controlled Oscillator (VCO) and a High Temperature VCO (HTVCO) having a voltage input and a frequency of oscillation dependent on the voltage input. The VCO uses a transistor providing a gain allowing for a sustained oscillation and having a capacitance that varies as a function of the voltage input. The voltage input is received at a gate of the transistor, when the latter is a Field Effect Transistor, and to a base when the transistor is a Bipolar Junction Transistor. The VCO also includes an inductance for controlling a base frequency of oscillation. The HTVCO may operate at temperatures of 200 to 300° C.

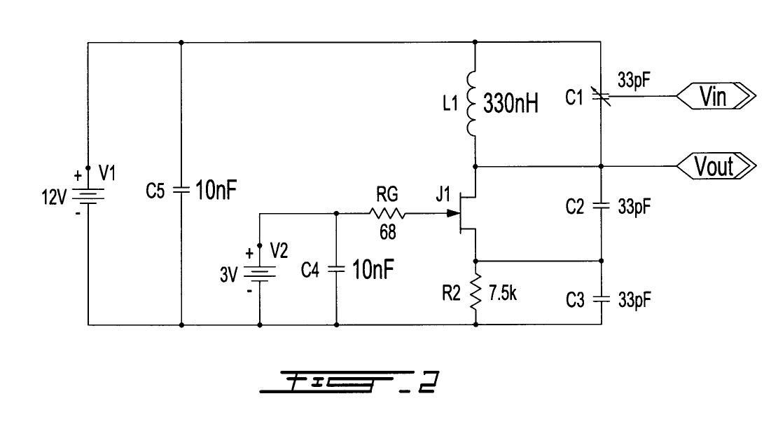

In accordance with another embodiment of the present invention, a prototype has been conceived to validate the present invention. The HTVCO prototype is based on a Colpitts oscillator. Typically in such oscillator, the capacitors and inductor values are adjusted to achieve the desired oscillation frequency. A voltage controlled capacitor (varactor) C1 (see FIG. 2) allows for variation of the oscillation frequency when its capacitance value is varied. In such a configuration, the transistor J1 is necessary to provide a gain to sustain the oscillation. The Colpitts oscillator also include a varactor, i.e. a variable capacitor, commercially available, but which is not specified for operation beyond 175° C. Moreover, manufacturers' specifications give the capacitance variation with respect to reverse voltage applied only for a temperature of 25° C. and never detail how the behaviour is affected by temperature. It is therefore difficult to use varactors in a high temperature design since high temperature performances are neither guaranteed nor specified and are susceptible to change without notice due to possible fabrication processes changes.

To overcome this issue, the present invention replaces the varactor by a transistor. As known from the literature, the internal capacitance of a transistor, in this case rated for high temperatures (as for Honeywell HTNFET), varies as its polarisation is changed. Such a mechanism permits the replacement of the varactor C1 in FIG. 2 by a transistor specified for the oscillator operating temperature. For example, the HTNFET from Honeywell is specified over −55° C. to 225° C. According to Honeywell, parts will typically operate at +300° C. up to a year with derated performances.

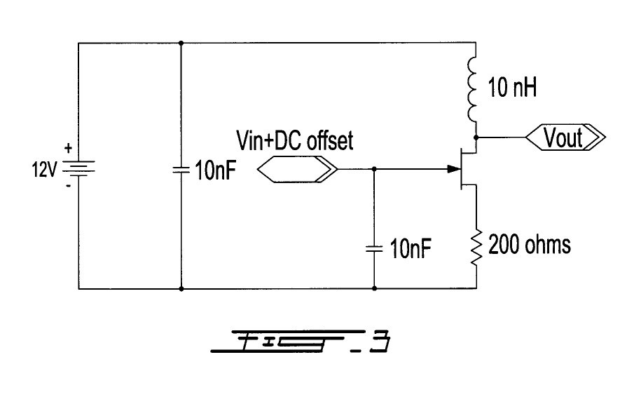

The HTVCO prototype of the present invention, shown in FIG. 3, uses a single transistor for: 1) providing the gain allowing for a sustained oscillation, and 2) acting as a variable capacitor controlling the frequency of oscillation.

The signal at the input port determines the oscillating frequency of the oscillator. Consequently, the circuit of FIG. 3 can be used as a frequency modulator when a modulating signal is fed to its input.

After validation of the circuit design on a breadboard, the alternate circuit, the prototype, was built using high temperature components and tested (see Table I).

TABLE I
HTVCO Components

| | | Max temp. | |
|---|---|---|---|
| Component | Company | (° C.) | Characteristics |
| Substrate | Rogers | 280 (Tg) | Rogers 4350 © |
| | Corporation | | |
| Capacitors | Novacap | 200 | C0G 25 V 1210, 10 nF |
| Transistor | Honeywell | 300 | HTNFET |
| | SSEC | | |
| Resistor | Ohmite | 350 | TA Series 5 W, 200 |
| | | | ohms |
| Inductor | MWS Wire | 240 | Polyimide HML 20 AWG. |
| | | | 10 nH. |
| Solder | Aim Solder | 280 | 80Au/20Sn wire solder |

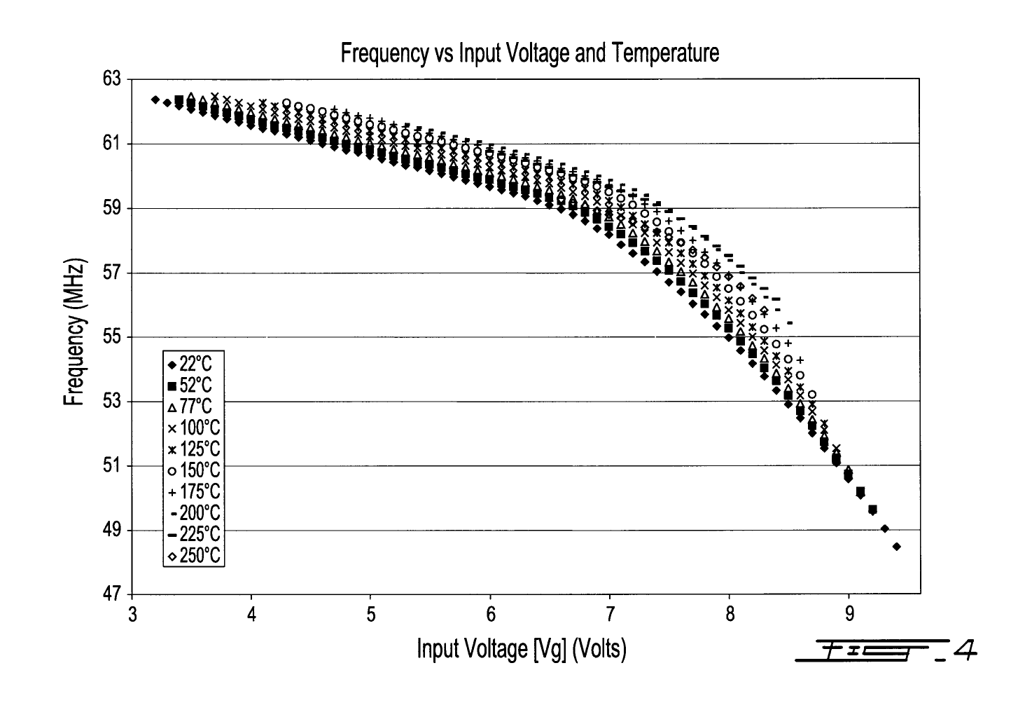

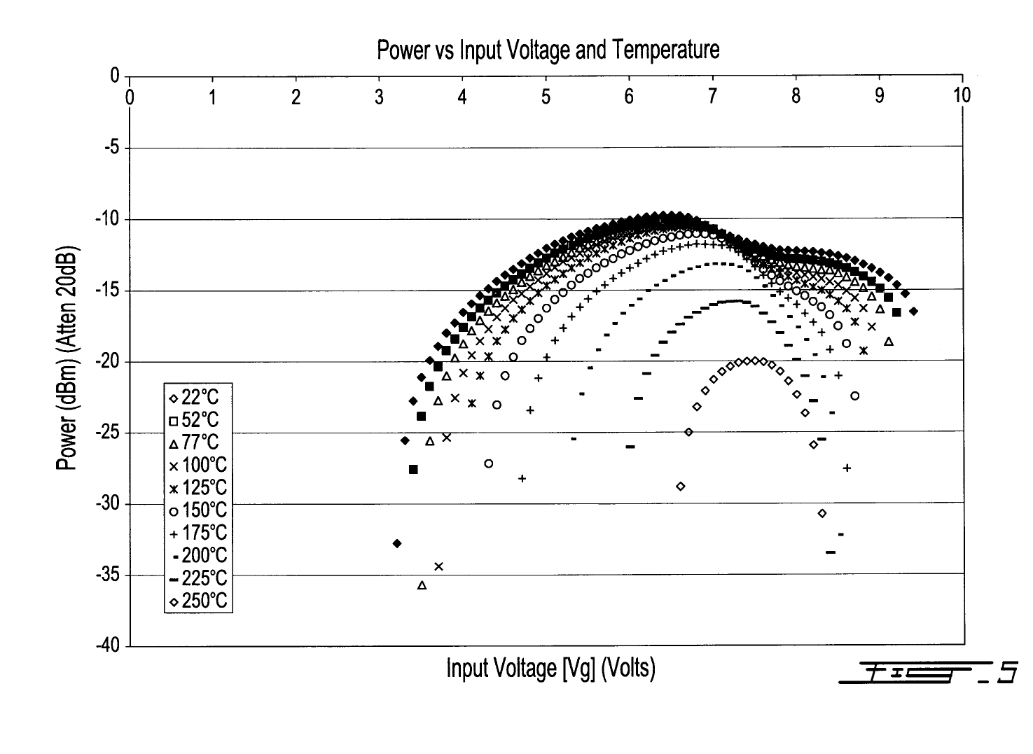

The circuit has been tested from room temperature (about 22° C.) to 266° C. It has sustained Pratt & Whitney Canada's high temperature transitory test by operating for 30 minutes at 250° C. Results are presented in FIGS. 4 and 5. FIG. 4 shows frequency versus input voltage and temperature while FIG. 5 shows power versus input voltage and temperature.

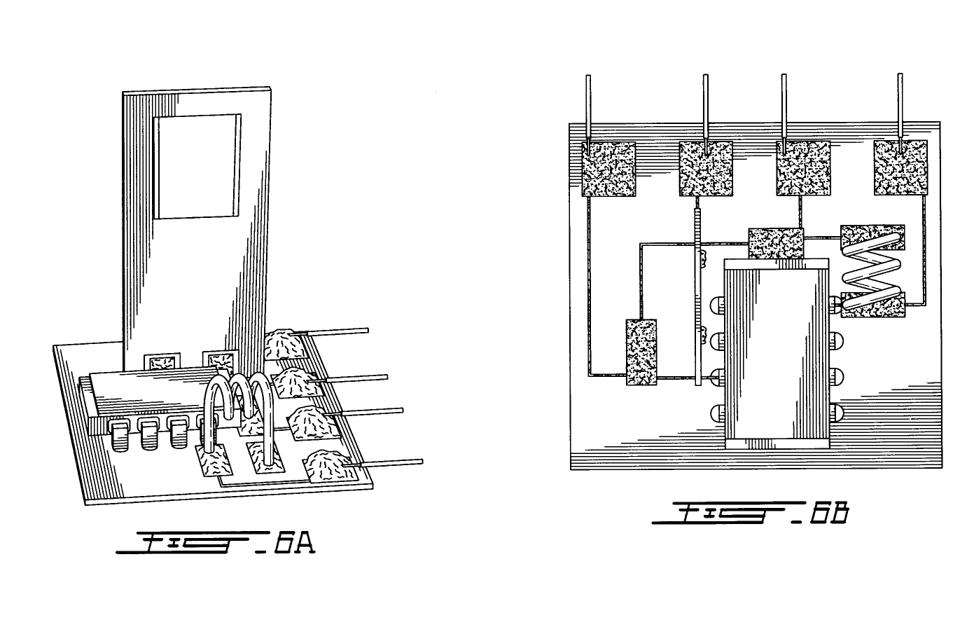

Photographs of the prototype are shown in FIG. 6.

An application of such oscillators is for transceivers, whether wired or wireless. An application of a wireless transceiver using the variable capacitance properties of a transistor can be for a high-temperature wireless sensor for point-to-point use or for use in a network.

The present invention also includes a method of designing the HTVCO and selecting a polarization voltage for the transistor within the HTVCO according to which polarization voltage yields a more suitable variable capacitance.

The VCO and HTVCO of the present invention may be used for multiple applications. For example, the HTVCO may be incorporated with a high-temperature sensor to realize a high-temperature sensor transceiver. Such a high-temperature sensor could be incorporated in a gas turbine.

Although the present invention has been described by way of preferred embodiments, many rearrangements may be performed to the present invention without departing from the scope of the attached claims, which define the scope of protection sought.

1. A High Temperature Voltage-Controlled Oscillator (HTVCO) having a voltage input and a frequency of oscillation dependent on said voltage input, said HTVCO comprising, a transistor having a capacitance that varies as a function of voltage input applied to said transistor, wherein said HTVCO operates at a temperature greater than about 200 C.

2. The HTVCO as defined in claim 1, wherein said transistor provides a gain allowing for a sustained oscillation.

3. A High Temperature Voltage-Controlled Oscillator (HTVCO) having a voltage input and a frequency of oscillation dependent on said voltage input, said HTVCO comprising, a transistor having a capacitance that varies as a function of voltage input applied to a gate of said transistor.

4. The HTVCO as defined in claim 3, wherein said HTVCO operates at a temperature greater than 85 C.

5. The HTVCO as defined in claim 1, 2, 3 or 4, wherein said transistor is a Field Effect Transistor.

6. A method of designing the HTVCO as defined in claim 5, comprising a step of selecting a polarization voltage for said FET within said HTVCO according to which polarization voltage yields a more suitable variable capacitance.

7. A high-temperature sensor transceiver comprising:
a high-temperature voltage-controlled oscillator as defined in any one of claims 1 to 5; and
a high-temperature sensor operatively coupled to said oscillator for wireless transmission of an output signal of said sensor.

8. A gas turbine engine incorporating the sensor transceiver as defined in claim 7.

9. A Voltage-Controlled Oscillator (VCO) having a voltage input and a frequency of oscillation dependent on said voltage input, said VCO comprising a transistor providing a gain allowing for a sustained oscillation and acting as a variable capacitor controlling the frequency of oscillation.

10. The VCO of claim 9, wherein the voltage input is received at a gate of the transistor.

11. The VCO of claim 10, further comprising an inductance for controlling a base frequency of oscillation.
